(19) United States
(12) Patent Application Publication
(10) Pub. No.: US 2019/0316593 A1
(43) Pub. Date: Oct. 17, 2019

(54) MOUNTING APPARATUS, COOLING DEVICE, AND CASING USING THE SAME

(71) Applicant: HONGFUJIN PRECISION ELECTRONICS (TIANJIN) CO.,LTD., Tianjin (CN)

(72) Inventors: YING-JIE DUAN, Tianjin (CN); YAN-NI YUAN, Tianjin (CN); GONG-WEN ZHANG, Tianjin (CN); HAN-YU LI, New Taipei (TW)

(21) Appl. No.: 16/006,973

(22) Filed: Jun. 13, 2018

(30) Foreign Application Priority Data
Apr. 16, 2018 (CN) 201810340580.7

(51) Int. Cl. F04D 25/06; F16M 13/02; F16B 2/22; F04D 29/60; H05K 5/02

(52) U.S. Cl. CPC F04D 25/0693; F16M 13/022; H05K 7/20718; F04D 29/601; H05K 5/0213; F16B 2/22

(57) ABSTRACT

A mounting apparatus used in a casing to mount a fan to a bracket and protect the electrical cables supplying the fan includes a pillar, a clipping member, and a connecting member. The pillar includes a first end and an opposite second end. The clipping member secures a cable of the fan and is fixed to the first end of the pillar. The connecting member mounting the fan is fixed to the second end of the pillar. The pillar defines a clipping slot for mounting to the bracket, the clipping slot is located between the first end and the second end.

### FIELD

The subject matter herein generally relates to cooling fan mountings.

### BACKGROUND

Server fans take power through the cables from the motherboard. The cables that are closer to the fans need to be fixed on the fan brackets. The cables are fixed to the fan holders in hooks, slots, etc., but the cables are frequently easily scraped, which affects quality of product.

Therefore, there is room for improvement within the art.

### BRIEF DESCRIPTION OF THE DRAWINGS

Implementations of the present disclosure will now be described, by way of example only, with reference to the attached figures.

FIG. 1 illustrates an isometric view of an embodiment of a mounting apparatus.

FIG. 2 illustrates an embodiment of a cooling device.

FIG. 3 illustrates an enlarged view of a portion A of the cooling device of FIG. 2.

FIG. 4 illustrates an isometric view of an embodiment of a casing.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “comprising” means “including, but not necessarily limited to”; it specifically indicates open-ended inclusion or membership in a so-described combination, group, series, and the like.

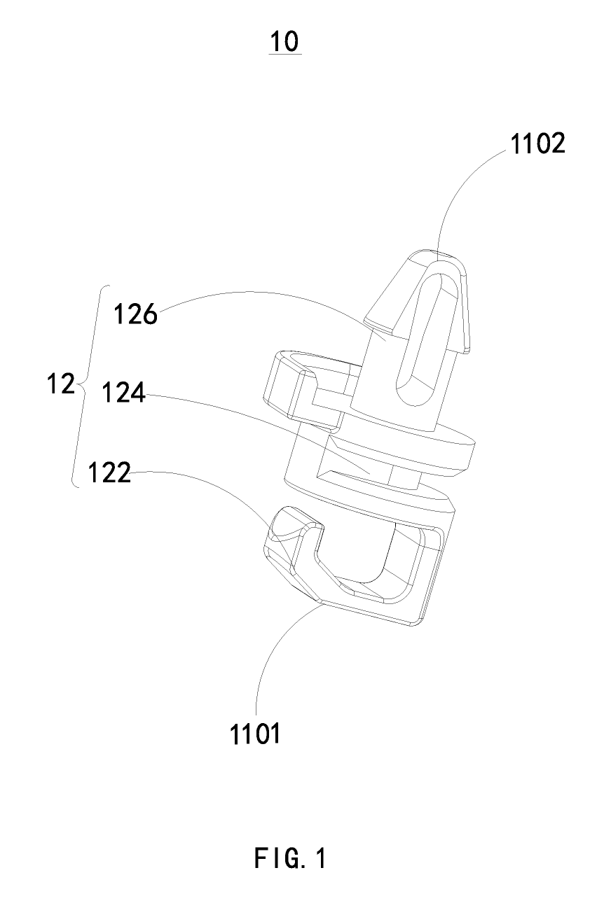

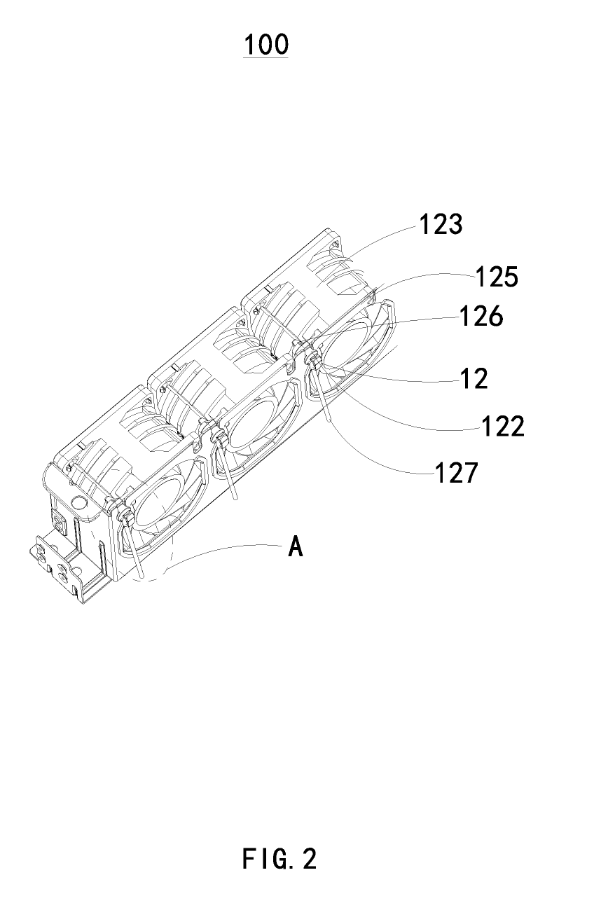

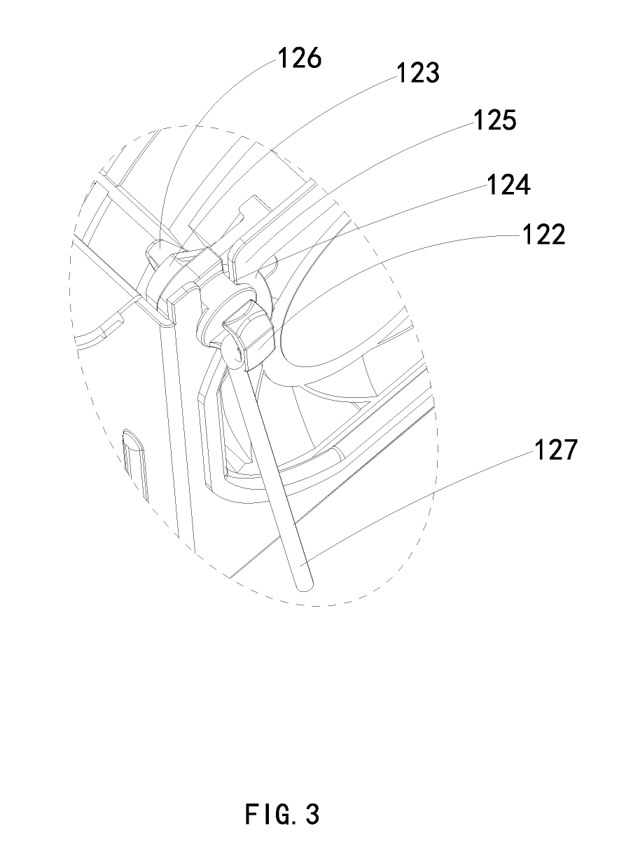

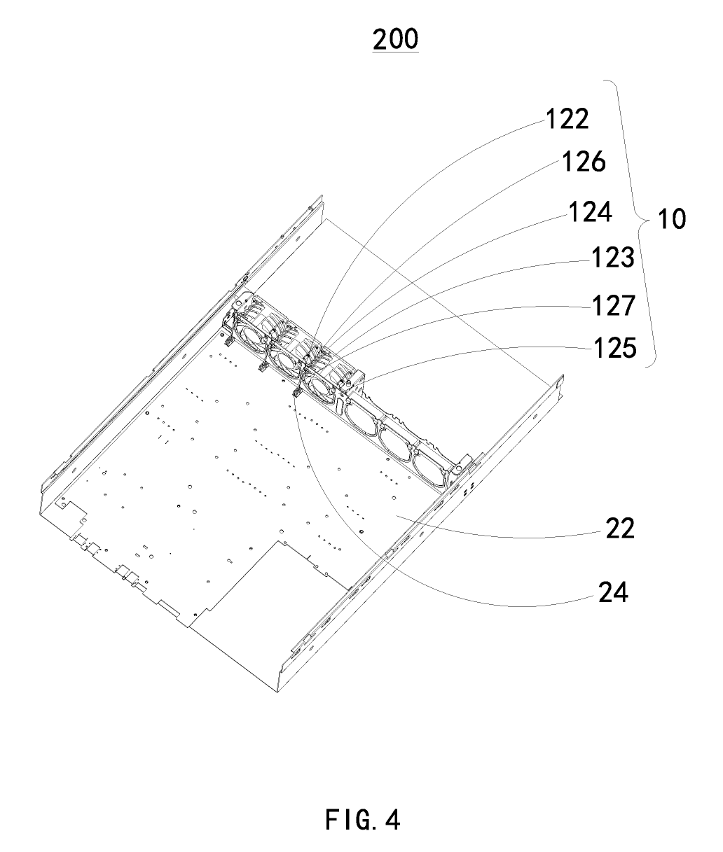

FIGS. 1 to 4 illustrate a casing 200. The casing 200 includes a bracket 125 and a cooling device 100. For example, the casing 200 can be a casing for accommodating server units, and the cooling device 100 can be mounted in the casing to cool the server units.

The cooling device 100 can include a fan 123, a cable 127, and a mounting apparatus 10.

The cable 127 is connected to the fan 123 to supply power to the fan 123.

The mounting apparatus 10 is used to mount the fan 123 to the bracket 125, and also used to neaten and protect the cable 127.

The mounting apparatus 10 can include a pillar 110, a clipping member 122, and a connecting member 126.

The pillar 110 can include a first end 1101 and a second end 1102 opposite to the first end 1101.

The clipping member 122 is used to mount the cable 127, and the clipping member 122 is fixed to the first end 1101 of the pillar 110.

The connecting member 126 is mounted to the fan 123, and the connecting member 126 is fixed to the second end 1102 of the pillar 110.

The pillar 110 defines a clipping slot 124 for mounting to the bracket 125. The clipping slot 124 is located between the first end 1101 and the second end 1102. For example, the clipping slot 124 can be located at a middle portion of the pillar 110.

For example, the clipping member 122 can be an L shaped hook, a free end of the cable 127 can pass through and be secured by the hook.

The mounting apparatus 10 can further include a latching portion 1261. The latching portion 1261 is located between the second end 1102 of the pillar 110 and the clipping slot 124. The connecting member 126 and the latching portion 1261 define a clamping to mount the fan 123.

In at least one embodiment, the connecting member 126 can be a protrusion. Correspondingly, the fan 123 defines a through hole (not shown) corresponding to the protrusion. The protrusion is connected in the through hole to mount to the fan 123.

The cooling device 10 can further include a main board 22. The main board 22 includes a power supply port 24, the cable 127 is connected to the power supply port 24.

The embodiments shown and described above are only examples. Even though numerous characteristics and advantages of the present technology have been set forth in the foregoing description, together with details of the structure and function of the present disclosure, the disclosure is illustrative only, and changes may be made in the details, including matters of shape, size, and arrangement of the parts within the principles of the present disclosure, up to and including the full extent established by the broad general meaning of the terms used in the claims.

What is claimed is:

1. A mounting apparatus for mounting a fan to a bracket, comprising:
a pillar comprising a first end and a second end opposite to the first end;
a clipping member to mount a cable of the fan, wherein the clipping member is fixed to the first end of the pillar; and
a connecting member to mounted to the fan, wherein the connecting member is fixed to the second end of the pillar;
wherein the pillar defines a clipping slot to mounted to the bracket, the clipping slot is located between the first end and the second end.

2. The mounting apparatus of claim 1, wherein the clipping member is a L shaped hook.

3. The mounting apparatus of claim 1, wherein the mounting apparatus further comprises a latching portion located between the second end of the pillar and the clipping slot, the connecting member and the latching portion define a clamping to mount the fan.

4. The mounting apparatus of claim 1, wherein the clipping slot is located at a middle portion of the pillar.

5. A cooling device comprising:
a fan;
a cable connected to the fan; and
a mounting apparatus for mounting the fan to a bracket, comprising:
a pillar comprising a first end and a second end opposite to the first end;
a clipping member to mount the cable, wherein the clipping member is fixed to the first end of the pillar; and
a connecting member to mount to the fan, wherein the connecting member is fixed to the second end of the pillar;
wherein the pillar defines a clipping slot to mounted to the bracket, the clipping slot is located between the first end and the second end.

6. The cooling device of claim 5, wherein the clipping member is a L shaped hook.

7. The cooling device of claim 5, wherein the mounting apparatus further comprises a latching portion located between the second end of the pillar and the clipping slot, the connecting member and the latching portion define a clamping to mount the fan.

8. The cooling device of claim 5, wherein the clipping slot is located at a middle portion of the pillar.

9. The cooling device of claim 5, wherein the connecting member is a protrusion; the fan defines a through hole corresponding to the protrusion; the protrusion is connected in the through hole to mount to the fan.

10. The cooling device of claim 5, wherein the cooling device further comprises a main board comprising a power supply port, the cable is connected to the power supply port.

11. A casing comprising:
a bracket; and
a cooling device comprising:
a fan;
a cable connected to the fan; and
a mounting apparatus for mounting the fan to the bracket, comprising:
a pillar comprising a first end and a second end opposite to the first end;
a clipping member to mount the cable, wherein the clipping member is fixed to the first end of the pillar; and
a connecting member to mount to the fan, wherein the connecting member is fixed to the second end of the pillar;
wherein the pillar defines a clipping slot to mounted to the bracket, the clipping slot is located between the first end and the second end.

12. The casing of claim 11, wherein the clipping member is a L shaped hook.

13. The casing of claim 11, wherein the mounting apparatus further comprises a latching portion located between the second end of the pillar and the clipping slot, the connecting member and the latching portion define a clamping to mount the fan.

14. The casing of claim 11, wherein the clipping slot is located at a middle portion of the pillar.

15. The casing of claim 11, wherein the connecting member is a protrusion; the fan defines a through hole corresponding to the protrusion; the protrusion is connected in the through hole to mount to the fan.

16. The casing of claim 11, wherein the cooling device further comprises a main board comprising a power supply port, the cable is connected to the power supply port.
